(19) United States
(12) Patent Application Publication
(10) Pub. No.: US 2025/0230522 A1
(43) Pub. Date: Jul. 17, 2025

(54) ASSEMBLY AND METHOD FOR PHOTOVOLTAIC (PV) SYSTEM RECYCLING

(71) Applicant: ETAVOLT PTE. LTD., Singapore (SG)

(72) Inventors: Qiu Xuan Cheryldine LIM, Singapore (SG); Zhi Peng LING, Singapore (SG); Chang-Kai Stanley WANG, Singapore (SG); Yong Heng SO, Singapore (SG)

(21) Appl. No.: 18/853,729

(22) PCT Filed: May 25, 2023
(86) PCT No.: PCT/SG2023/050365

§ 371 Date: Oct. 3, 2024

(30) Foreign Application Priority Data
Jun. 6, 2022 (SG) 10202250065Q

(51) Int. Cl. C22B 11/00; C22B 7/00

(52) U.S. Cl. CPC C22B 11/046; C22B 7/007

(57) ABSTRACT

An assembly and a method for photovoltaic (PV) panel recycling is disclosed. The assembly comprises (a) a mechanical means to remove aluminium frames; (b) a furnace; (c) a cooling station; (d) a wet bench; (e) a filtration system; (f) a tilt furnace, and (g) a plurality of crushers for used in crushing recovered glass and silicon wafers.

### CROSS REFERENCE TO RELATED APPLICATION

This patent application claims the benefit of priority of Singapore Patent Application No. 10202250065Q, filed 6 Jun. 2022. The above application is incorporated by reference herein.

### FIELD OF THE INVENTION

The present disclosure relates generally to assembly and method for PV panel recycling, and in particular, a fully integrated indoor assembly for solar panel recycling and the method of recycling using the same.

### BACKGROUND OF THE INVENTION

Silicon based photovoltaic (PV) systems capacity has increased exponentially over the years, as reported by the International Renewable Energy Agency (IRENA), with a global installed PV capacity exceeding 700 GW as of end 2020, and is predicted to rise further to 1600 GW in 2030 and onwards to 4500 GW in 2050. Correspondingly, the PV-related waste is also expected to increase, and effective PV end-of-life management solutions are required.

This is a significant move towards reducing reliance on conventional energy sources which worsens the climate change issue. However, the amount of PV-related waste generated from these systems is expected to rise as well, where the current PV waste stands at 250k tonnes, and is predicted to increase to 8M tonnes by 2030 and 78M tonnes by 2050. If considering an average module power of 400 W, the total number of decommissioned solar panels amounts to 625k, 20M, and 195M pieces respectively. This is a massive quantity of decommission panels that needs to be handled in time to come.

At the moment, the conventional way of handling this PV waste is to turn to landfill dumping, which raises issues relating to the reduction in usable land space and increasing environmental pollution. It is also a huge waste of resources if these potentially reusable constituent materials within the solar panels end up disposed. Therefore, it is important to recycle these constituent materials as much as possible. In this regard, delivering a circular PV economy is necessary, which ensures the sustainability of the PV ecosystem both at the point of installation and at their end-of-life management. By breaking down the decommissioned solar panels into their respective components and repurposing these recovered materials back into new PV systems, millions of new panels can be reproduced. FIG. 12 shows exemplification of the circular PV economy related to solar panel production by year 2030.

EP 2997169 A1 entitled “Process for treating spent photovoltaic panels” discloses treatment of photovoltaic end-of-life panels, such as those made of CdTe and crystalline and amorphous silicon. The process involves automated physical and chemical operations that, combined in a sequence, allow recovering glass in the first place and also tellurium, zinc, cadmium, iron, and concentrate silicon, TiO₂ and silver. By means of this process the different types of panel can also be treated all together, without any kind of preliminary selection.

WO2017009062A1 entitled “Method for recycling photovoltaic solar cells module” discloses recycling/recovering a core (9) of a silicon solar cells module (8) in its raw components comprising the steps of: d) providing a core (9) of a silicon solar cells module wherein the cells (6) are interconnected by connection ribbons (5) and embedded in an encapsulation layer (4) said encapsulation layer (4) being sandwiched between a back sheet (7) and a front glass plate (3); e) introducing the core (9) of the silicon solar cells into a reactor; f) dismantling the solar cells core (9) by hydrothermal treatment under subcritical atmosphere to generate recovered clean glass component and a residual laminate (10).

The cumulative PV capacity is predicted to reach 1600 GW by 2030, while the cumulative PV panel waste would also reach to the scale of millions of tonnes as well. Therefore, it becomes necessary to recycle the components from these decommissioned panels, so that there would be enough raw material recovered to produce an equally enormous number of new panels—thus delivering a circular PV economy. Additionally, with the incoming wave of panels to be dealt with, it also becomes necessary to create a high throughput PV recycling system capable of handling this volume.

Often, a general reluctance to adopt PV panel recycling stems from the concern of recycling costs as compared to the conventional approach of landfill dumping. Therefore, the efficiency of this PV recycling process becomes critical, and the purity of the recovered materials has to be as high as possible. This ensures that these recycling activities deliver both environmentally and financially feasible outcomes, which in turn helps to encourage more PV asset owners to adopt the recycling approach instead of landfill dumping for their end-of-life panels.

FIG. 13 shows composition percentage of a typical silicon-based solar panel which contains the following components: glass (74%), encapsulant (7%), silicon (3%), backsheet (4%), silver/Ag (0.05%), and other invaluable elements such as aluminium/Al, zinc, lead, copper and tin (11.95%). The values in brackets represent the weight percentages. Once extracted from the solar panels, these respective components can then be transferred into the next stage of recycling, where they will be passed on to both upstream and downstream partners. The upstream recyclers take in valuable metals such as Ag and Al, while the downstream recyclers take in the other components for proper disposal. Either way, a significant percentage (>90%) of these components can be reused and repurposed into new solar panels, which helps to establish a circular PV economy.

Currently, most recyclers handle PV waste by crushing into smaller bits. These pieces will then either be resold for a low price or dumped into landfills. Alternatively, commercial tools could also be purchased to deframe the panels prior to their crushing, but the efforts often stop at this point. On the other hand, laboratory-scale recycling methodologies have been demonstrated with single standalone solar cells bought directly from solar cell/panel manufacturers. There have been limited reports of the integration of both processes at the solar panel level. This leaves a gap, where there are current technical solutions for surface-level solar panel dismantling and cell-level stripping of silver and aluminium but not an integrated linkway between these two, which is required for a complete recycling of solar panels.

The present invention discloses an indoor based integrated PV panel recycling solution and the method of recycling using the same. The preferred embodiments described herein with goals to facilitate an effective and efficient recovery of the raw materials (>90%) to realise a circular PV economy outcome. The key benefits of this PV recycling setup and its various embodiments include: (1) clean removal of panel backsheet and EVA encapsulant while leaving the glass piece intact, (2) tackling the panel recycling problem from a high volume, high throughput perspective, (3) selective extraction for Ag without contamination of Al, (4) rapid Ag extraction process for high throughput recycling, (5) simple to operate design and (6) scalable and suitable for industrial use. By adopting the approach in this invention disclosure, solar panels can now be efficiently and effectively recycled in an environmentally friendly approach.

The present invention provides a solar panel recycling turnkey to address the above-mentioned problems. Firstly, decommissioned waste panels will be deframed by a mechanical tool to remove the aluminium frames and junction boxes. Once this is complete, the panels will then be sent for a uniquely developed incineration process to remove the backsheet and the EVA encapsulant. This process will be described in details in the following sections. Once the incineration is complete, the glass piece would be retrieved in one piece, which can be reutilized by downstream consumers. The solar cells would also be detached and will proceed on to the chemical process for silver extraction. The developed silver extraction know-how will also be elaborated in this invention disclosure. After the silver extraction, the remaining stripped silicon pieces would be rinsed and sold to downstream consumers. The extracted silver would be purified and melted into an ingot. To summarize, with the turnkey indoor based solar panel recycling solution elaborated in this invention disclosure, over 90% of the constituent materials within each solar panel can be recovered and reutilized in new applications, thus delivering an economically sustainable environmental impact.

### SUMMARY OF THE INVENTION

This invention seeks to provide a turnkey solution for solar panel recycling.

Apart from the initial mechanical process, the subsequent thermal process for the removal of the backsheet and EVA encapsulant as well as the stripping and recovery processes for the silver contained within the solar cells were developed in-house. As covered above, the key novelty and benefits of this disclosed process method and the respective device design and its modified embodiments can be summarised as: (1) tackling the full-size solar panel recycling needs with a high throughput process, (2) clean removal of panel backsheet and EVA encapsulant to obtain access to the underlying silicon solar cells while leaving the glass piece intact, (3) selective extraction for Ag without contamination of Al, (4) rapid Ag extraction process for high throughput recycling, (5) easy to operate design and (6) scalable and suitable for industrial scale deployment. Using the approach in this invention disclosure, solar panels can now be recycled effectively in an environmentally friendly manner.

Using the approach in this invention disclosure, the effective extraction of the valuable Ag metal from decommissioned solar panels has been demonstrated on a conceptual front as well as on an industrial-scale adaptation. At the moment, most research efforts center around the smaller-sized silicon solar cells. This leaves a huge gap for the PV recycling industry to fill as there are no other viable solutions for panel scale metal recovery. Existing reported methods also often lead to crushed cells as the end product without the metal recovery aspects, which reduces the value of these end components. In this invention disclosure, panels can be recycled whole and its components extracted with high purity and little to no damage. The individual pieces are also left intact at the end of the process. These are in line with industrial needs and differs from typical academic research in terms of the processing stages, the techniques used, the products retrieved, and most importantly, the load throughput. Additionally, this Ag metal extraction process is also highly scalable and adoptable.

A main object of the present invention is to provide an assembly and a method for solar panel recycling, wherein the assembly and method provides the advantages as follows:

1. Tackles recycling from a large-scale perspective (panels in this invention disclosure versus cells in literature). This allows the invention to cater to a wider range of customers, which now includes solar asset owners and solar EPC or O&M companies, on top of the existing group of cell and module manufacturers. This extends the outreach effort towards landfill prevention.
2. Clean removal of panel backsheet and EVA encapsulant while leaving the glass piece intact. This allows for a higher resale value of the glass pieces which could be reused for the manufacture of new solar panels.
3. Utilizes an extraction method with significantly higher selectivity for Ag, which ultimately leads to a recovered Ag metal with higher purity as compared to existing methods in literature which dissolves both Al and Ag simultaneously. With a higher material purity, it can be sold for higher prices which is a good motivator for solar cell and panel recycling.
4. Rapid Ag extraction process: The Ag stripping process is significantly faster (˜30 seconds) as compared to most other published reports (hours scale) [2-8]. Therefore, it is suitable for high throughput cell and panel recycling.
5. Simple design, easy to handle and operate.
6. Scalable and suitable for industrial use; can be set up and duplicated in other countries and regions.

Yet another main object of the present invention is to provide an assembly and method for solar panel recycling, which provides advantages, if deploy for industrial use, as follows:

1. Conveyor line for transportation of solar panels/cells from station to station.
2. Each individual station is designed to selectively remove target components while leaving the other components intact. With this specific selectivity, components can be singled out and solely targeted which leaves the remaining portions undamaged.
3. Process line is automated, requires minimal manual supervision. This allows for higher throughput for larger batches to be processed in each single run.
4. Process is clean, produces little waste by-products
5. Stations are modular, and are modifiable portion by portion while not disrupting the other stations/the remaining parts of the line.

To demonstrate the effectiveness of this recycling process, test solar cells and solar mini-modules were subjected to screening and optimization studies for both the thermal process as well as the silver stripping and recovery process as elaborated in the following sections.

### (A) Thermal Incineration of Panel Backsheet and EVA Encapsulant:

Subsequent to the initial deframing step for the removal of the aluminium frames and junction boxes, the backsheet and EVA encapsulant need to be removed from the solar panel to get access to the solar cell (wafers) which are embedded in between. This step is necessary in order for the cells to proceed to the stripping and recovery steps next. Mini-modules were loaded into an industrial furnace and incinerated at several varying temperatures and holding durations to identify a suitable set of conditions. The tested temperatures ranged from 200 to 600° C., and from 30 minutes to 1 hour. The observations were obtained and shown in FIG. 1, which illustrates visual observation of the backsheet and EVA encapsulant after the mini-modules were incinerated in the various as-stated temperatures and durations.

As seen in FIG. 1, the backsheet (and therefore EVA encapsulant) was observed to be intact at 200° C. and 300° C. However, a visible decomposition was clearly observed once the temperature was raised to 400° C. A clean burn-off of the backsheet and EVA encapsulant was obtained when the temperature was further raised to 500° C. After the incineration process, despite low quantities of soot observed on the exposed solar cell and glass, the top tempered glass remained intact as one piece. This glass piece can be washed and cleaned, ready for its next reuse.

From the positive initial results shown in FIG. 2, which illustrates further optimization studies for the thermal incineration process. As previously indicated in FIG. 1, since 500° C. was already suitable in clearing off the backsheet and EVA encapsulant, higher temperatures of 550° C. and 600° C. were tested in this extended study to determine the feasibility of higher process temperatures for throughput improvement. At 550° C., it could be observed that the backsheet and EVA encapsulant could be burned off more cleanly without sooting, and at 600° C., the glass became brittle and started to break off in chunks. As such, the optimal temperature and duration suitable for this process is deemed to be 550° C. and 30 minutes respectively.

### (B) Silver Metal (Aq) Stripping Process:

Next, the effectiveness of this turnkey recycling solution could be demonstrated by the rapid Ag stripping process. Solar cells without encapsulant were soaked into a plastic container filled with 500 mL of 50% diluted nitric acid solution (1 HNO₃:1 H₂O) and a working bubbler. Complete Ag stripping could be achieved within ˜30 seconds and was reproducible across 10 different solar cells. The comparison between the stripped and unstripped cells are featured in FIG. 3, which provides images showing the cells before and after the stripping process. The changes on the busbars and fingers after the stripping process be noted.

TABLE 1
Stripping duration averaging for the tested 10 wafers and resulting
x-ray fluorescence (XRF) results. Values are in percentages.

| | Time taken | | |
|---|---|---|---|
| Wafer | for Ag | Ag (after | Al (after |
| number | stripping (s) | stripping) | stripping) |
| Control | — | 95 | 97-99 |
| 1 | 32.21 | Not detected | 99 |
| 2 | 29.11 | Not detected | 99 |
| 3 | 31.00 | Not detected | 99 |
| 4 | 30.10 | Not detected | 99 |
| 5 | 32.18 | Not detected | 99 |
| 6 | 32.14 | Not detected | 99 |
| 7 | 28.24 | Not detected | 99 |
| 8 | 30.10 | Not detected | 99 |
| 9 | 32.02 | Not detected | 99 |
| 10 | 22.35 | Not detected | 99 |
| Average | 29.95 | — | — |

With the 10 tested wafers, the average time taken for complete Ag stripping is ˜30 seconds. The concentration percentages of Ag and Al remaining on the stripped wafers were also tested preliminarily with an x-ray fluorescence (XRF) gun. After the stripping process, no Ag could be detected for the 10 cells, while the amount of Al remained constant at 99%.

TABLE 2
ICP-OES results for 3 additional wafers after the stripping process.

| | | Stripped | Remaining on | Total | Stripping |
|---|---|---|---|---|---|
| | | amount | stripped wafer | amount | efficiency |
| | Sample | (mg) | (mg) | (mg) | (%) |
| Ag | 1 | 90.8 | 0.08 | 90.88 | 99.91 |
| | 2 | 103.1 | 0.021 | 103.121 | 99.97 |
| | 3 | 102.2 | 0.023 | 102.223 | 99.98 |
| Al | 1 | 2.7 | 151.9 | N.A. | N.A. |
| | 2 | 1.9 | 169.4 | N.A. | N.A. |
| | 3 | 1.0 | 166.0 | N.A. | N.A. |

The reproducibility of this experiment was demonstrated for 3 additional wafers. These wafers were subjected to the same stripping process, after which the stripped pieces were crushed into smaller pieces and digested with pure HNO₃ for 5 minutes. These mixtures were then filtered and ICP-OES was performed on the filtrate. For ICP-OES, calibration was performed with 2, 5 and 10 ppm Ag and Al standards. The results for the ICP-OES measurements are presented above in Table 2. The amount of Ag remaining on the stripped wafers are minimal at 0.08, 0.021 and 0.023 mg.

With the combination of these results above, the Ag stripping process in this invention disclosure is rapid at ˜30 seconds, is highly selective for Ag as compared to Al (˜50 to 1), and is highly efficient with an average stripping efficiency of 99.95%.

### Silver Metal (Aq) Recovery Process:

FIG. 4 indicates visual changes that occur with each step of conversion from AgNO₃ into Ag metal in accordance with the present invention.

After the Ag has been stripped, it would remain in the nitric acid (HNO₃) solution as silver nitrate (AgNO₃; Ag⁺). This has to be precipitated into a solid and then reduced into Ag metal before it can be resold to upstream consumers. For the conversion pathway into silver metal, the small-scaled solar cells were used for this process formulation. These steps are further described in this invention:
1. In order to precipitate the silver ions, hydrochloric acid (HCl; 110 mL) is first added into the reaction mixture. This converts AgNO₃ into silver chloride (AgCl), which is insoluble in aqueous medium. Therefore, it precipitates out as a white solid with the following reaction:

AgNO₃+HCl→AgCl+HNO₃ a.
2. After AgCl is precipitated, it is then filtered and washed with deionised water. The filtration component is important here, because it isolates the AgCl product from its acidic medium. With the implementation of this filtration step, the amount of materials required for the subsequent workup of AgCl can be reduced. This would then reduce the cost of the subsequent steps as well reduce the amount of chemical waste generated from those steps. After rinsing, the AgCl is then added into 90 mL of 50% diluted NaOH (1 NaOH:1 H₂O). This converts AgCl into silver hydroxide (AgOH), which is a necessary step because the Ag complex needs to exist in a form which can be reduced safely to obtain silver metal. The reduction of AgCl likely produces chlorine gas, which is toxic to the human respiratory system when inhaled in large quantities. As such, this step is also necessary for safety considerations.
   a. As AgOH is formed, it quickly breaks down into brown silver oxide (Ag₂O) solid in a spontaneous decomposition reaction.
   b. AgCl+NaOH→AgOH+NaCl; 2 AgOH→Ag₂O+H₂O (spontaneous)
3. With Ag₂O obtained at this stage, it is ready for reduction into silver metal. In this reaction mixture, dextrose (35.5 g) was added. This step is described as a redox reaction, where Ag₂O is reduced into Ag metal, and dextrose is oxidized into gluconic acid:
   a. Ag₂O+C₆H₁₂O₆→2 Ag+C₆H₁₂O₇+H₂O
   b. Ag metal is precipitated as a sludge, which must be filtered and washed with deionised water. This sludge contains a mixture of Ag metal and undissolved, unreacted dextrose, which can burned off in a subsequent incineration process.
4. Before Ag metal can be purified and molded into an ingot, it must be first be rid of any excess unreacted reagents. The filter paper which contains the Ag sludge mix is incinerated in an industrial furnace at 800° C. for 30 minutes, giving a residue product mixture of Ag metal and soot, possibly from an incomplete or partial burning of the organics.
5. With this residue product, it is then loaded into a tilting furnace, where the furnace would be fired up to melt the Ag metal. Once molten, the Ag metal will be poured out of this furnace into a heated mold, where it would form an ingot.
6. Lastly, the casted Ag ingot is left aside to cool, after which it would be rinsed with deionized water and dried. Rinsing with sulfuric acid can also be performed in the case that the impurities contain other metals.

The optical images of these processes are presented below. The total time required for these processes is estimated to be ˜2 hours. The purity of Ag metal obtained in these processes is ˜95%.

To summarise the above results, the turnkey indoor based PV recycling solution described in this invention consists of: an initial deframing step to remove the aluminium frames and junction boxes from the solar panels, a subsequent incineration step at 550° C. for 30 minutes for thermal removal of the panel backsheet and EVA encapsulant, a rapid, selective Ag stripping process with 50% diluted HNO₃ solution, and the Ag recovery multistep process which requires the addition of HCl, NaOH and dextrose. The obtained Ag metal is purified by a thermal process before molding into ingot form. Rinsing of these ingots finalizes the Ag recovery process.

### BRIEF DESCRIPTION OF THE DRAWINGS

The above and other aspects, features, and advantages of the present disclosure will be more clearly understood from the following detailed description, taken in conjunction with the accompanying drawings.

FIG. 1 shows visual observation of the backsheet and EVA encapsulant after the mini-modules were incinerated in the various as-stated temperatures and durations in accordance with the present invention.

FIG. 2 illustrates further optimization studies for the thermal incineration process in accordance with the present invention.

FIG. 3 illustrates images showing the cells before and after the stripping process in accordance with the present invention, wherein there are changes on the busbars and fingers after the stripping process.

FIG. 4 indicates visual changes that occur with each step of conversion from AgNO₃ into Ag metal in accordance with the present invention.

FIG. 5 indicates recycling line concept for solar panels on the industrial scale level in accordance with the present invention.

FIG. 6 indicates a perspective view of holder and the front view of the holder in accordance with the present invention, wherein the shaded area of the front view represents deframed solar panels.

FIGS. 7A-7C respectively illustrate a perspective view, bottom view and top view of the carrier for the solar cells for the chemical process in accordance with the present invention, wherein FIG. 7D is a close-up of the top view when the carrier is loaded with solar cells.

FIG. 8 is an overview of the PV recycling pilot line layout in accordance with the present invention, which comprises a deframing machine, a furnace, a cooling station, a wet bench station (chemical station), a filtration system, a tilt furnace, and a plurality of crushers.

FIG. 9 shows close-up images of the individual components of FIG. 8 of the PV recycling pilot line layout plan in accordance with the present invention.

FIG. 10 shown the wet bench in accordance with the present invention, which comprises an incoming loading section, a bath container for stripping and recovery, a container for DI water rinsing, a partition for drying, and an outgoing/unloading section.

FIG. 11 shows a proposed floorplan layout/equipment footprint in accordance with the present invention.

FIG. 12 shows exemplification of the circular PV economy related to solar panel production by year 2030.

FIG. 13 shows composition percentage of a typical silicon-based solar panel.

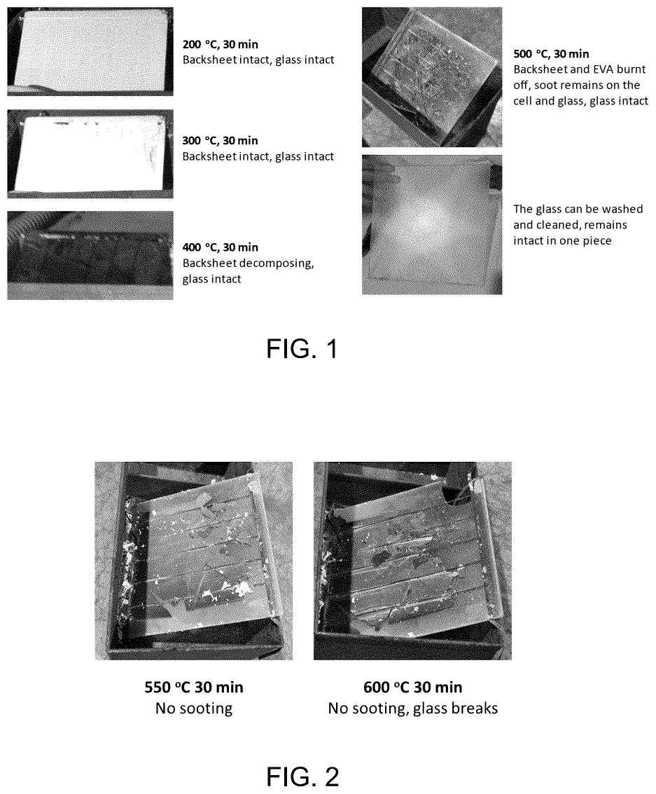

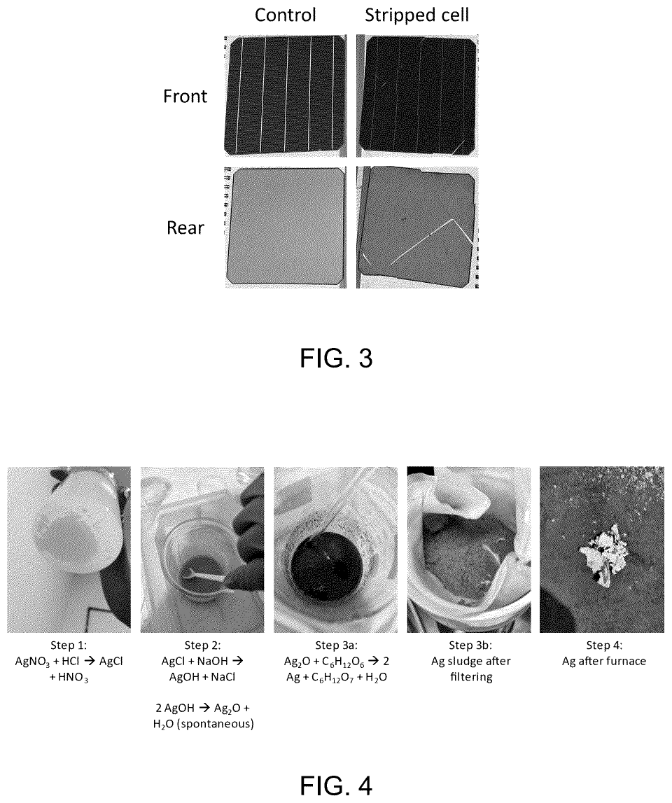

### DETAILED DESCRIPTION OF THE PREFERRED EMBODIMENT

Hereinafter, embodiments will be described in detail with reference to the accompanying drawings. While the disclosure is subject to various modifications and alternative forms, specific embodiments thereof are shown by way of example in the drawings and are explained in detail in the description. However, the disclosure should not be construed as being limited to the embodiments set forth herein, but on the contrary, the disclosure is intended to cover all modifications, equivalents, and alternatives falling within the spirit and scope of the embodiments. In the drawings, the sizes or shapes of elements may be exaggerated for convenience and clarity of description.

In general, the present invention provides an assembly and a method for photo voltaic (PV) cells, panels or system recycling.

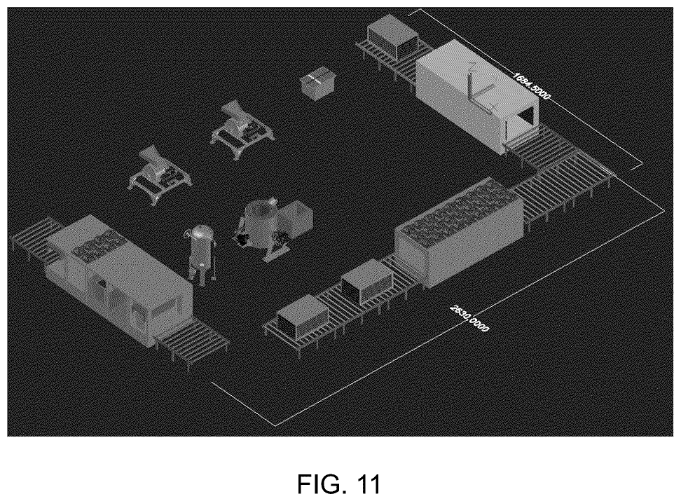

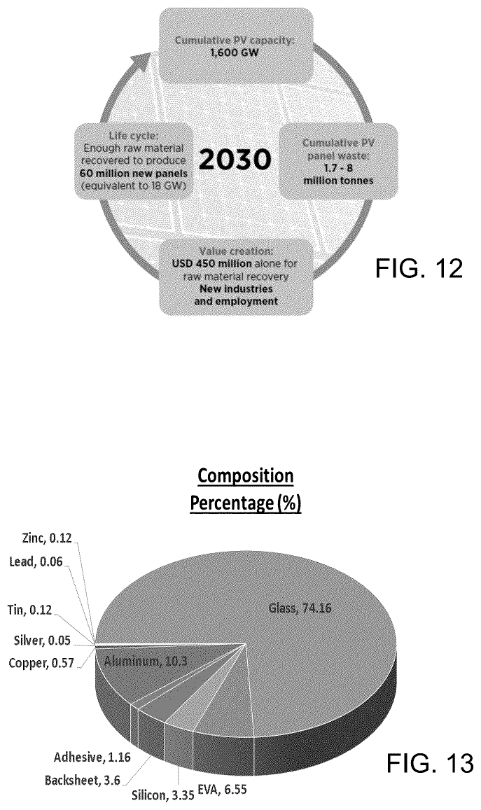

FIG. 8 illustrates an assembly for photovoltaic (PV) panels recycling which comprises a deframing machine (10), a furnace (20), a cooling station (30), a wet bench station (40), a filtration system (50), a first crusher (52), a second crusher (54), and a tilt furnace (60). There are several components in each solar panel that can be removed or extracted by employing the assembly and method of the present invention. These components will be removed in the following order: Al frame together with the junction box, following by removing of the backsheet of the solar panel, and EVA encapsulant, and finally the removal of Ag and Si. FIGS. 8 and 11 show a list of the key process stations to remove these components mentioned above, with a detailed description of the process hereinafter.

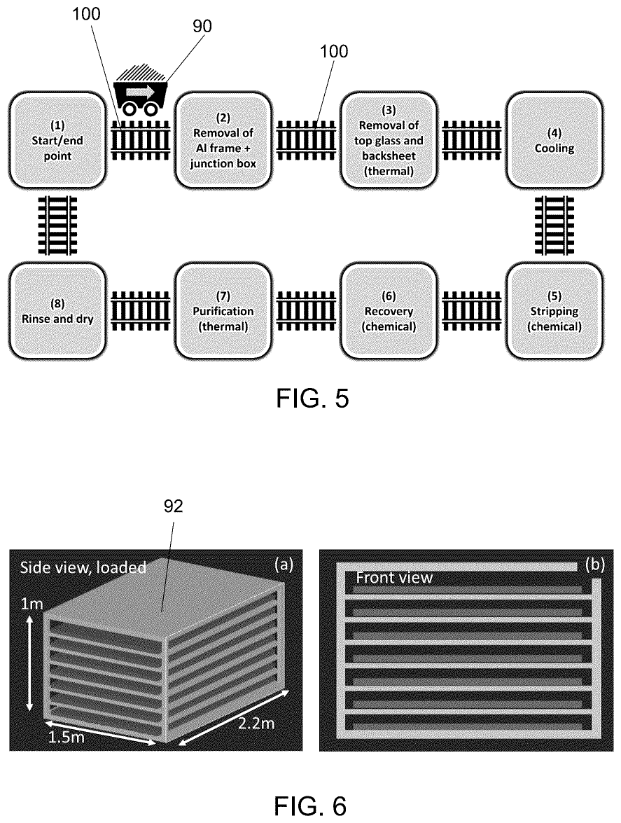

As shown in FIG. 5, which the recycling line concept for solar panels on the industrial scale level in accordance with the present invention is indicated. Schematically, the recycling process in accordance with the preferred embodiment of the present invention is as follows:
1. At start/end point: this is where the solar panels will be loaded into a carrier (90) which will be transported around the various stations (station 1 to station 8) through a conveyor belt system (100). The processed solar cells will also be transported to this point when the entire process is completed. The implementation of the conveyor system (100) marks the automation of this recycling line, which differentiates itself from that of a laboratory setting.
2. At station 2: Al frame+junction box removal [mechanical]: this step is necessary to remove the Al frames and junction boxes attached to the outermost framework of the solar panels. This will be carried out by a commercially available tool designed specifically for this purpose.
3. At station 3: Removal of top glass and backsheet via EVA encapsulant incineration [thermal]—after the solar panels are stripped on the outside, this is followed by the rear backsheet layer and the EVA encapsulant layers removal to get access to the embedded solar cells. This step will be carried out by placing the solar panels into a furnace where an incineration temperature of 550° C. would be applied. The holding temperature is optimal at 30 minutes. This ensures that the backsheet would be burnt off, and that the EVA encapsulant that is holding the backsheet and top glass together would melt and degrade off as well. After this process is completed, the products that would be obtained are the top glass and the individual solar cells.
4. At station 4: Cooling [post-thermal]—before proceeding onto the next step, the cells need to undergo a cooling session as they would exit the furnace with a high temperature. The cells need to be cooled to room temperature prior to the next process.
5. At station 5: Ag stripping process [chemical]—in this stage, the cells would be soaked into a polypropylene/polyethylene basin containing 50% nitric acid bath (1 nitric acid:1 DI water) for 30 seconds. A bubbler or agitator should be operational during the stripping process. With this step, Ag would be stripped off the cells while leaving Al untouched on the wafer surface.
6. At station 6: Precipitation process [chemical]—this process focuses on the treatment of the dissolved Ag. A series of conversions take place at this step. Firstly, HCl would be added into the basin. This would convert the AgNO₃ from the previous step into white AgCl, which would precipitate out in an aqueous medium. Secondly, NaOH is added into the mixture to neutralise the excess acid and also to convert AgCl into Ag₂O. This reaction is spontaneous and produces a brown precipitate. Additionally, dextrose is added into the mixture until a black, jelly-like precipitate is formed, which results from a redox reaction occurring between the Ag and dextrose moieties. In this case, Ag₂O is reduced into Ag metal, while dextrose is oxidized into gluconic acid. This mixture would be filtered at the end, producing a dull-grey Ag sludge. All reagents added at this step were added until no more conversions were observed/no more reaction is observed.
7. At station 7: Purification—at this stage, the Ag sludge would be transferred into a furnace which would burn this mixture at 800° C. for 30 minutes to remove the excess (unreacted) reagents. This leaves behind Ag metal, soot and dross/scum. This mixture would then be transported into another custom-made furnace where it would be melted into molten state, and impurities would be removed from the Ag metal as they float upwards. After the Ag metal has been purified, it would be loaded onto a preheated mold to form Ag ingot.
8. At station 8: Wash bay—this is where the silver-extracted solar cells as well as the precipitated Ag will be washed and dried. Both components will be transported back to the start/end point, station 1, for collection. This step is important so that the collected components will be pure and free from the remnants of the earlier steps.
9. Optional station 9: Additionally, the recovered glass and silicon wafers would be crushed with a mechanical crusher. This would reduce those materials into smaller fragments and pieces, which would ease the transport, packaging and storage of these materials to further downstream recyclers.

### Sample Holders

FIG. 6 indicates a perspective view of holder and the front view of the holder in accordance with the present invention, wherein the shaded area of the front view represents deframed solar panels. In accordance with the present invention, the holder design is used for the thermal process of solar panel recycling. This will be used when the panels are sent into the furnace for the incineration of the backsheet and EVA encapsulant. The holder will be made of an alloy containing stainless steel and nickel (Ni) of the following dimensions: 2.2 m (l)×1.5 m (w)×1 m (ht) as depicted in (a) of FIG. 6. This holder has an array of slots in which the deframed solar panels will be horizontally inserted, with the glass facing downwards and backsheet side facing up, as shown in (b) of FIG. 6. During the incineration process, as the backsheet and EVA encapsulant are removed, the glass at the bottom will act as a tray to hold onto the loose, exposed solar cells. The individual solar panels will be separated from each other by ˜13 cm each. This holder is designed to hold up to 7 panels, an estimated total panel weight of 140 kg, and will be transported in and out of the furnace via a conveyor belt system.

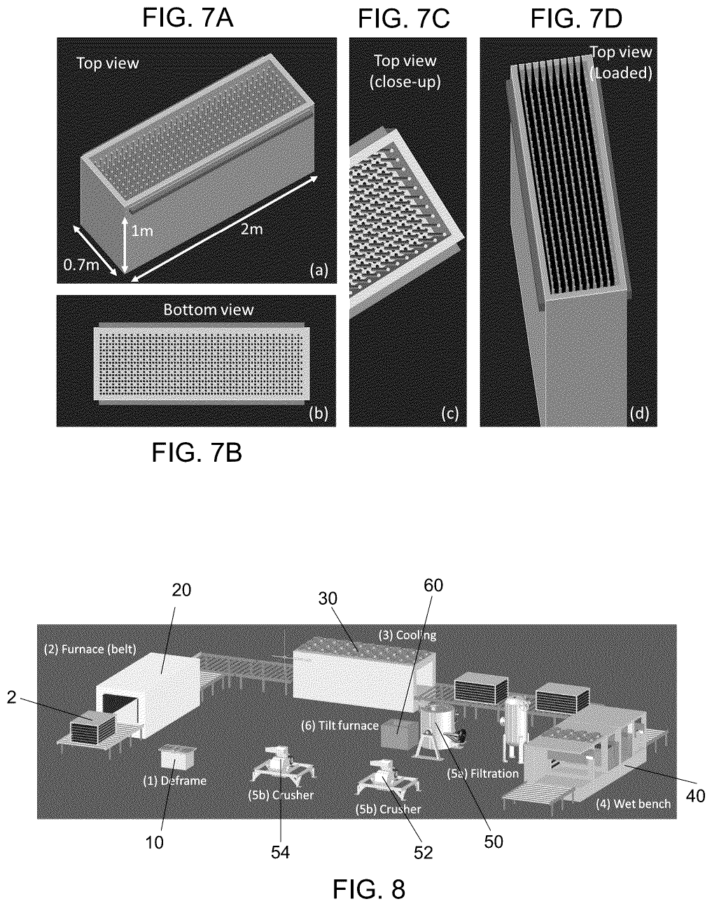

After the incineration process, the exposed solar cells would be obtained in smaller, loose pieces. For the chemical station, these solar cells will be processed in a polypropylene/polyethylene carrier with dimensions of 2 m (l)×0.7 m (w)×1 m (ht) as shown in FIG. 7. These carriers are designed such that they are able to hold the loose solar cells in a vertical manner. There is an array of holes at the bottom of this carrier design to facilitate the flow of chemicals into and out of this carrier. The carrier will be removed from the soaking solution once Ag is fully stripped from the solar cells.

### Overview of the Recycling Pilot Line Design

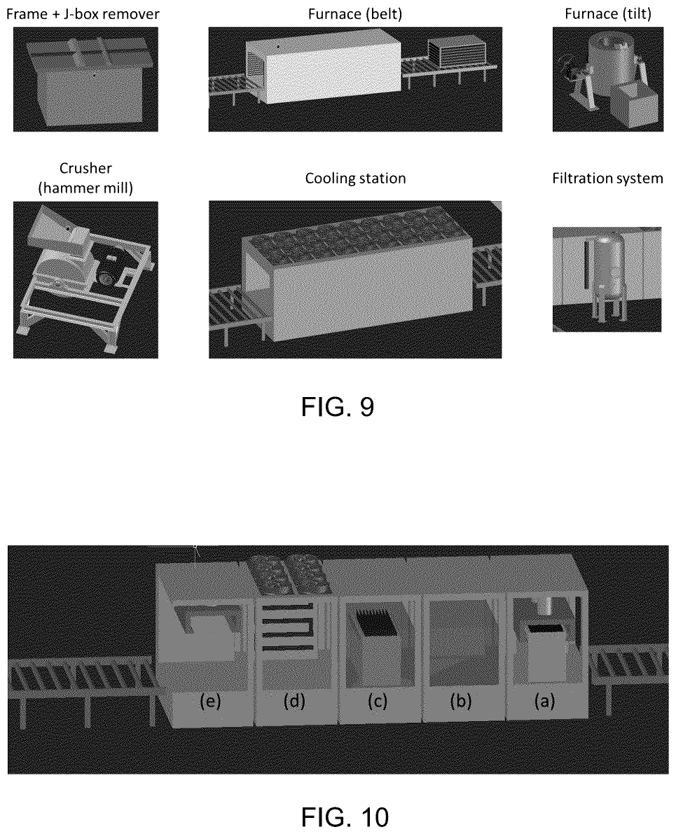

FIG. 8 shows the overall layout of the PV recycling pilot line at the industrial scale. The idea conception for the PV recycling line is materialized here, with this setup consisting of the following equipment: a deframer, a furnace, a cooling station, a wet bench (chemical station), a filtration system, a tilt furnace, and crushers. A close-up view of the individual equipment is provided in FIG. 9. The key processes are as follows: mechanical—to remove the aluminium frame and junction box, and to crush the glass and silicon wafers; thermal—to incinerate off the backsheet and EVA encapsulant, and to mold raw Ag into Ag ingot; and chemical—to strip Ag from the solar cells and to recover Ag. The individual processes are described below:
(1) Panel deframing—this is the initial step for the recycling line. The solar panels to be recycled must first have their aluminium frames and junction boxes removed. This includes the removal of any inverters and copper wiring. This tool is commercially available.
(2) Furnace—the deframed panels will be inserted into the holder as described above, and will be transported into the furnace via a conveyor belt line. The incineration process will be conducted at 550° C. for 30 minutes before removing the panels from the furnace.
(3) Cooling—the panels would then be transported into the cooling station via an extension of the conveyor belt line to be cooled down to room temperature.
(4) Wet bench—with the conveyor transport, the panels would be brought over to the chemical station once they are cooled. From here, the loose, exposed solar cells would be inserted into the chemical holder (described above), which would then be soaked into a larger container containing the stripping solution.
   a. The stripping solution used here is 50% diluted HNO₃ (1 HNO₃:1 DI H₂O)
   b. The conversion of AgNO₃ into AgCl requires 110 mL of HCl per 20 panels' worth of Ag
   c. The conversion of AgCl into Ag₂O requires 90 mL of NaOH per 20 panels' worth of Ag
   d. The conversion of Ag₂O into Ag requires 35.5 g of dextrose per 20 panels' worth of Ag
   e. The stripped solar cells would require washing and rinsing
(5) Post wet-bench
   a. Filtration—when AgNO₃ is converted into AgCl, this has to be filtered first before proceeding on to the next step on AgCl conversion into Ag₂O
   b. Filtration—the Ag sludge obtained from the final step of the chemical process needs to be filtered and rinsed from the unreacted, excess reagents
   c. The stripped solar cells which have been rinsed and washed at the chemical station would be manually brought over to the crusher for further dismantling. Small pieces of the wafers would be collected at the end.
(6) Tilt furnace—the Ag sludge that was filtered, rinsed and washed in step 5a would be brought over to this tilt furnace. The temperature would be fired up to ˜1100° C. to melt the Ag sludge. The impurities that cannot be melted e.g. the dross and scum would be scooped out and sifted aside. The pure Ag melt would then be poured onto a preheated mold to form the Ag ingot. This ingot must be rinsed and dried before it is ready for resale.

### Wet Bench

FIG. 10 shows a detailed view of the wet bench chemical process. The wet bench chemical process comprises a total of 5 segments, which at the end is responsible for the stripping of Ag from the solar cells as well as the retrieval of the stripped wafers. These 5 segments are partitioned as follows:
(a) Incoming loading—this is the start of the chemical station, where the loose, exposed solar cells will be transported to before the stripping begins. The transportation will be executed via a conveyor belt system.
(b) Reaction bath—this is where the stripping of Ag and its subsequent recovery is performed. It is a single container capable of handling the multi-step reaction.
(c) DI H₂O rinsing—the stripped wafers will be brought over to this section to be rinsed thoroughly with DI water.
(d) Dryer—the stripped wafers have to be dried prior to being unloaded to be sent for mechanical crushing
(e) Unloading bay—dried-stripped wafers will be sent here for unloading.

### Floorplan Layout/Equipment Footprint

FIG. 11 shows a proposed floorplan layout/equipment footprint in accordance with the present invention. Herein, the proposed floorplan layout/equipment footprint of the recycling pilot line is described. The dimensions of the floorplan is estimated to be 17 m (w)×26 m (l). The outer perimeter encompasses the conveyor belt transportation system which primarily runs through the furnace, the cooling station and the wet bench (chemical station). The smaller equipment like the deframing machine, the filtration system, the tilt furnace and the crushers are positioned within this rectangular boundary.

In accordance with the present invention, additional preferred embodiments could be obtained with modifications.

The first modified embodiment looks similar to FIG. 8, except that an additional furnace is added after the filtration step. This furnace would be used for the purification of the Ag sludge after the filtration process. In this additional incineration step, soot would most likely be produced from the burning of the excess, unreacted reagents such as dextrose. The addition of this furnace would then allow for an independent incineration-purification step without the clogging up of the tilt furnace.

The second modification would be to the wet bench (chemical station), where the reaction container would be used for Ag stripping and recovery. Instead of using HCl, NaOH and dextrose for the recovery stage, it could be replaced with zinc dust or copper strips for an alternative single-displacement reaction to precipitate Ag metal from AgNO₃.

### Commercial Applications of the Present Invention

This invention can be applied to both p- and n-type silicon solar cells in existing setups/systems, and can be adapted and modified to suit the needs of future panels. Single, standalone solar cells and wafers can also be recycled with this recycling technology. This includes solar cells that are partially processed, and low grade/scrapped solar cells which are rejected from solar cell/panel manufacturing plants as well as EPC and O&M companies. This allows our recycling initiative to bring in a higher resale revenue.

This design described in this invention is scalable in several aspects, hence it is able to cater to a wide range of solar cells and panels, which includes both the small and large variants. The recovery of raw materials as described by this invention is of a much higher concentration by weight, which therefore permits a higher resale revenue as well.

High load throughput is permissible with this invention design, which allows for high recycling processing per workday. This enables more solar cells and panels to be recycled at a time, which allows for the recycler to cater to more customers to speed up the rate of raw materials recovery and subsequently the re-input of these raw materials to generate newer solar cells and panels. By extension, this also means that this invention is capable of enabling the recycling of the high value precious metal Ag from the solar panel wastes, which is key to achieving a sustainable solar recycling business model. This would tackle the current common challenge faced by the commercial solar e-waste industry.

An industrial-scale setup can be built with the design described in this invention. Automated processing can also be implemented in this design. With an automation in the process line, less manpower is needed, and the recycling productivity can be increased. This helps to generate a higher resale revenue.

There are potential limitations to both the thermal and chemical steps in the above hybrid and modified models:
1. [Thermal]—the furnace will be operating at high temperatures (550° C.) to ensure complete burn-off of the EVA encapsulant as well as the backsheet. This temperature is high enough such that many by-products will be obtained when plastics are burnt in the process. Furthermore, the burning off of the EVA encapsulant and backsheet would also produce CO₂ on complete burning. Therefore, it is important to attach the furnace to a scrubber which would filter off toxic and harmful gases before release into the environment. A quencher is also required to quench off the hot flue gas produced from this incineration process.
   a. The high operating temperature also implies that a suitable fire extinguisher should be made accessible in case of overheating failures.
   b. With the use of a suitable scrubber, about 80-90% of CO₂ produced from the incineration process can be removed, so this would not be a major concern.
2. [Chemical]—in a large-scale operation, the volumes of liquid reagents would inevitably amount to a sizeable portion. Therefore, it is imperative to have the appropriate safety measures in place such as spill kits or spillage solutions. For the waste liquids, it should be appropriately treated before disposal. Proper training and risk assessment and prevention measures will help to mitigate and improve the safety measures. Proper labwear should also be worn when dealing with the wet bench processes.
3. Facility housing—sufficient spacing should be given to house these stations and for manpower to move around with ease. An additional spacing should be set aside for a medical bay in case of emergency and the setups should not block any escape routes. Panel storage space should also be allocated for incoming decommissioned panels as well as recycled samples exiting from the recycling line.
4. Throughput integration between equipment—the throughput obtained from the various stages could vary greatly from each other. This can be overcome by optimizing the design for each station. For example, the number of tools per process station could be adjusted so that the overall throughput would be balanced across the line.

While the invention has been described in connection with certain preferred embodiments, it is not intended to limit the scope of the invention to the particular forms set forth, but, on the contrary, it is intended to cover such alternatives, modifications, and equivalents as may be included within the true spirit and scope of the invention as defined by the appended claims.

1. An assembly for recycling of solar panel having an aluminium frame, backsheet and EVA encapsulant, comprising:
(a) a mechanical means to remove aluminium frames and junction boxes of a solar panel to be recycled, wherein the solar panel is deframed;
(b) a furnace having an incineration temperature of 550° C. which provides incineration process to the deframed solar panel from (a), wherein the backsheet and the EVA encapsulant are being removed, and glass piece is being retrieved as one piece;
(c) a cooling station for cooling the solar panel exited from the furnace as the solar panel is of high temperature;
(d) a wet bench which is being used to proceed the solar panel with a Ag stripping process;
(e) a filtration system for filtering of Ag from the Ag stripping process in (d),
(f) a tilt furnace for melting of Ag from Ag sludge, wherein the tilt furnace burns the Ag sludge at 800° C. for 30 minutes to remove any unreacted agents being used in Ag stripping in (d),
(g) a plurality of crushers for used in crushing recovered glass and silicon wafers into smaller fragments and pieces for easy transport, packaging and storage for further downstream recyclers.

2. The assembly for recycling of solar panel as set forth in claim 1, further comprising a conveyor belt (100) being used to link from the mechanical means to the furnace, from the furnace to the cooling station, and from the cooling station to the wet bench, and from the wet bench to the filtration system, from the filtration system to the tilt furnace, and from the tilt furnace to the crushers.

3. The assembly for recycling of solar panel as set forth in claim 1, wherein a carrier (90) is deployed to deliver solar panel in recycling process.

4. The assembly for recycling of solar panel as set forth in claim 1, wherein a holder is used in holding the solar panel for thermal processes in the assembly.

5. A method for solar panel recycling, the method comprising the steps of:
providing solar panel with a plurality of solar cells, aluminium frame and junction boxes, and having one surface of a glass bonded by an encapsulant and a backsheet being coated between the one surface of the glass and the encapsulant;
deframing of the solar panel by a deframing machine to remove any inverters and copper wirings on the solar panel, wherein the deframed panels are then inserted into a holder;
incinerating the deframed panels in the holder at a furnace being conducted at 550° C. for a period of 30 minutes, and transferring the incinerated panels in the holder to a cooling station where the panels are cooled to room temperature;
stripping the solar cells which are being inserted into the holder and soaked in a container to obtain a stripped solution, wherein the container contains a stripping solution;
washing and rinsing the stripped solar cells and filtering the stripped solution to obtain a Ag sludge; and
filtering, rinsing and washing the Ag sludge and then proceeding to a tilt furnace to obtain Ag melt.

6. The method as set forth in claim 5, wherein the temperature of the tilt furnace is fired up to 1100° C. to melt the Ag sludge.

7. The method as set forth in claim 5, further comprising the step of pouring the Ag melt onto a preheated mold to form Ag ingot.

8. The method as set forth in claim 5, wherein the striping solution comprises 50% diluted HNO3.

9. The method as set forth in claim 5, wherein the Ag stripping is completed within 30 seconds.

10. The method as set forth in claim 5, wherein hydrochloric acid is first added to the stripped solution to precipitate the silver ions so as to convert AgNO₃ into AgCl.

11. The method as set forth in claim 5, wherein EVA encapsulant is being removed when the incineration temperature is raised to 550° C., and the glass is also obtained as one piece.

12. The method as set forth in claim 5, wherein the backsheet is being removed when the incineration temperature is at 550° C.

13. The method as set forth in claim 5, wherein the optimal temperature and duration for the process to obtain glass of the solar panel is 550° C. and 30 minutes respectively.

14. The method as set forth in claim 5, wherein a conveyor belt system is used to transport the solar panels.

15. The method as set forth in claim 9, wherein the temperature of the Ag stripping at 800° C.
